(19) United States
(12) Patent Application Publication
(10) Pub. No.: US 2018/0233430 A1
(43) Pub. Date: Aug. 16, 2018

(54) PROCESSING DEVICE AND PROCESSING SYSTEM

(71) Applicant: NEC CORPORATION, Tokyo (JP)

(72) Inventor: Atsushi KOZATO, Tokyo (JP)

(73) Assignee: NEC CORPORATION, Tokyo (JP)

(21) Appl. No.: 15/751,311

(22) PCT Filed: Aug. 18, 2016
(86) PCT No.: PCT/JP2016/003763

§ 371 Date: Feb. 8, 2018

(30) Foreign Application Priority Data
Aug. 25, 2015 (JP) 2015-165918

(51) Int. Cl. H01L 23/38; G06F 1/20; H04L 25/03

(52) U.S. Cl. CPC H01L 23/38; H04L 25/03866; G06F 1/20

(57) ABSTRACT

The present invention addresses the problem of reducing the number of terminals of a processing device while achieving both communication with another device and temperature adjustment of at least part of the processing device. To solve this problem, a processing device is provided with a temperature control signal generation unit, a data signal generation unit, a transmission signal generation unit, and a sending unit. The temperature control signal generation unit generates a temperature control signal which is to be transmitted to a temperature control means and which has identification information attached thereto for allowing another device which performs communication with the processing device other than the temperature control means to identify the temperature control signal. The data signal generation unit generates a communication data signal to be sent to the other device. The transmission signal generation unit generates a transmission signal obtained by superimposing the temperature control signal and the data signal. The sending unit sends the transmission signal to the temperature control means and the other device.

### TECHNICAL FIELD

The present invention relates to a processing system configured to adjust a temperature of a device capable of communicating with another device.

### BACKGROUND ART

FIG. 1 is a conceptual diagram illustrating an example of a general processing system configured to adjust a temperature of a device capable of communicating with another device.

A processing system 091 includes a processing device 001, a drive device 004, and a temperature adjusting device 005.

The processing device 001 includes an arithmetic device 002 and can perform arithmetic processing by a function of the arithmetic device 002. The processing device 001 is typically a central processing unit (CPU). The processing device 001 includes terminals 011 to 013 being input/output terminals. The processing device 001 transmits a communication data signal to a terminal 015 of an arithmetic device 003 being an arithmetic device other than the arithmetic device of the processing device 001, via the terminal 012 through a wire 022. The processing device 001 also receives a communication data signal transmitted from a terminal 014 of the arithmetic device 003 through a wire 023 via the terminal 013. In this way, the processing device 001 can communicate with the arithmetic device 003. Furthermore, the processing device 001 transmits a signal for controlling the drive device 004 to the drive device 004 via the terminal 011.

The drive device 004 applies a drive voltage to the temperature adjusting device 005 by the signal transmitted from the processing device 001. The temperature adjusting device 005 adjusts a temperature of the arithmetic device 002 with the applied drive voltage.

Note that PTL 1 discloses a device configured to cool a power element with a thermoelectric transducer, and PTL 2 discloses a method for cooling a semiconductor element by using a Peltier element.

NPL 1 describes scrambling on a communication data signal, which will be described below.

NPL 2 discloses an example of a communication protocol that can be used for data communication in the present invention, which will be described below.

### CITATION LIST

### Patent Literature

[PTL 1] Japanese Laid-open Patent Publication No. 2003-179196
[PTL 2] Japanese Laid-open Patent Publication No. 2008-263164

### Non Patent Literature

[NPL 1] NIPPON TELEGRAPH AND TELEPHONE EAST CORPORATION, technical reference material about high-speed digital transmission service (SONET/SDH interface), <METRO HIGH LINK> the second edition, July 2002, [searched on 24 Jul. 2015] on the Internet (https://www.ntt-east.co.jp/business/service/support/ether/refer/pdf/mhl_t ec.pdf)
[NPL 2] Renesas Electronics Corporation, RX111 group, hardware section of user's manual, Rev. 1.20, pp. 794, 795, December 2014, [searched on 24 Aug. 2015] on the Internet (http://documentation.renesas.com/doc/products/mpumcu/doc/rx_family/r01uh0365jj0120_rx111.pdf)

### SUMMARY OF INVENTION

### Technical Problem

However, in the processing system 091 illustrated in FIG. 1, a dedicated terminal 011 being an input/output unit for transmitting a signal for controlling the drive device 004 to the drive device 004 needs to be installed on the processing device 001. A processing device is often required to be reduced in size. In this case, the number of terminals that can be installed on a processing device is limited, and it is often difficult to secure the terminal 011 being the input/output unit. Furthermore, assigning the dedicated terminal 011 being the input/output unit for transmitting a signal for controlling the drive device 004 to the drive device 004 needs installation of a dedicated wire for transmitting the signal. The wire is preferably omitted as much as possible in terms of size reduction of a product including the processing system 091.

An object of the present invention is to provide a processing device and a processing system including the processing device, capable of reducing the number of input/output units of the processing device while achieving both communication with another device other than the processing device and temperature adjustment of at least part of the processing device.

### Solution to Problem

A processing device according to the present invention includes a temperature control signal generation unit, a data signal generation unit, a transmission signal generation unit, and a sending unit. The temperature control signal generation unit generates a temperature control signal that is to be transmitted to a temperature control means and that has identification information attached thereto for allowing another device communicating with the processing device other than the temperature control means to identify the temperature control signal. Herein, the temperature control means is a means for performing a temperature adjusting output on at least part of the processing device. In a process of converting an input signal input to a temperature control means to the temperature adjusting output, the temperature control means performs high-frequency cutoff processing of allowing a low frequency to pass on the input signal or at least one signal among signals processed from the input signal. The data signal generation unit generates a communication data signal to be transmitted to the another device. The transmission signal generation unit generates a transmission signal obtained by superimposing the temperature control signal and the data signal. The sending unit sends the transmission signal to the temperature control means and the another device.

### Advantageous Effects of Invention

A processing device and a processing system including the processing device according to the present invention can reduce the number of input/output units of the processing device while achieving both communication with another device other than the processing device and temperature adjustment of at least part of the processing device.

### BRIEF DESCRIPTION OF DRAWINGS

FIG. 1 is a conceptual diagram illustrating an example of a typical processing system;

FIG. 2 is a conceptual diagram illustrating a configuration of a processing system in a first example embodiment;

FIG. 3 is an image diagram illustrating signal processing in a signal smoothing device and a drive device;

FIG. 4 is a conceptual diagram illustrating an example of a signal transmitted from a terminal of a processing device;

FIG. 5 is a conceptual diagram illustrating a configuration of a processing system in a second example embodiment;

FIG. 6 is an image diagram illustrating an example of a section of a Peltier element;

FIG. 7 is an image diagram illustrating an example of the processing system in the second example embodiment;

FIG. 8 is an image diagram illustrating a processing system including a temperature detecting device;

FIG. 9 is a conceptual diagram illustrating a configuration of a processing system in a third example embodiment;

FIG. 10 is an image diagram illustrating an example of a signal input to a drive device;

FIG. 11 is an image diagram illustrating an example of output of the drive device;

FIG. 12 is a conceptual diagram illustrating a configuration of a variation of the processing system in the third example embodiment;

FIG. 13 is an image diagram illustrating signal processing in signal smoothing devices and a drive device; and

FIG. 14 is a conceptual diagram illustrating a configuration of a processing device having the smallest configuration of the present invention.

### DESCRIPTION OF EMBODIMENTS

### Description of Terms

Main terms used in [Description of Embodiments] are described below.

A “processing device” represents a device capable of communicating with another device other than the processing device and capable of causing a temperature adjusting device to adjust a temperature of at least part of the processing device by transmitting a temperature adjusting signal to the temperature adjusting device.

A “processing system” represents a system including a processing device and a temperature adjusting device to which a temperature adjusting signal is transmitted from the processing device.

### First Example Embodiment

The present example embodiment is an example embodiment about a processing system including a processing device in which a terminal for transmitting a communication data signal also serves as a terminal for temperature adjustment.

### [Configuration and Action]

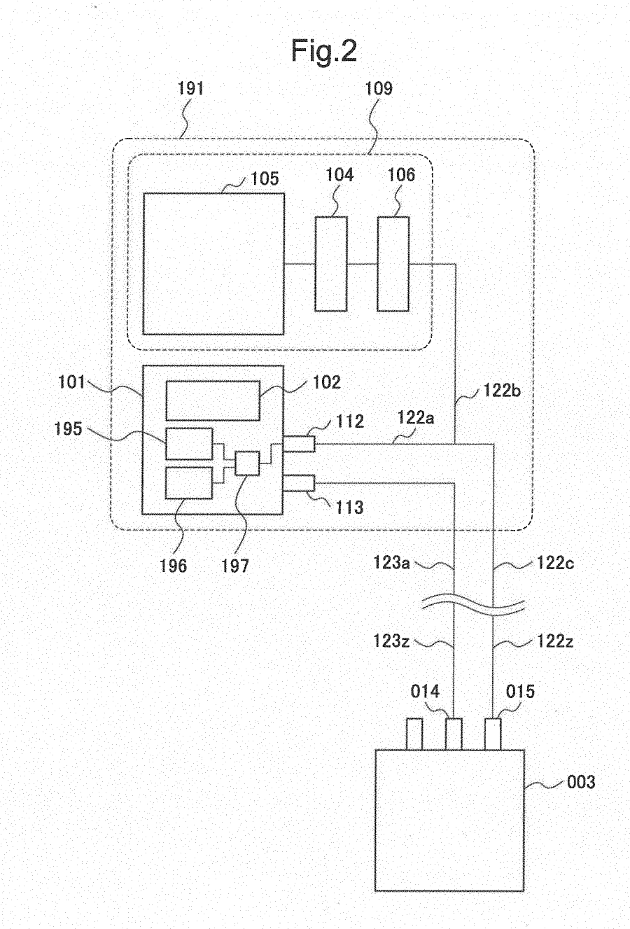

FIG. 2 is a conceptual diagram illustrating a configuration of a processing system 191 in the present example embodiment.

The processing system 191 includes a processing device 101, a drive device 104, and a temperature control device 109.

The temperature control device 109 is a temperature control means for controlling a temperature of at least part of the processing device 101, and includes a signal smoothing device 106, the drive device 104, and a temperature adjusting device 105.

The processing device 101 includes an arithmetic device 102, a temperature control signal generation unit 195, a data signal generation unit 196, a transmission signal generation unit 197, a terminal 112, and a terminal 113.

The temperature control signal generation unit 195 generates a temperature control signal for controlling the temperature control device 109. The generated temperature control signal is transmitted to the transmission signal generation unit 197.

The data signal generation unit 196 generates a communication data signal to be transmitted to an arithmetic device 003. The generated communication data signal is transmitted to the transmission signal generation unit 197.

The transmission signal generation unit 197 generates a transmission signal obtained by superimposing the temperature control signal transmitted from the temperature control signal generation unit 195 and the communication data signal transmitted from the data signal generation unit 196.

The transmission signal generated by the transmission signal generation unit 197 is transmitted to the arithmetic device 003 via the terminal 112 through wires 122a, 122c, and 122z via a terminal 015. The processing device 101 can receive a communication data signal transmitted from the arithmetic device 003 via a terminal 014 through wires 123z, 123a via the terminal 113. As described above, the processing device 101 can communicate with the arithmetic device 003.

Note that as long as the wire 122c and the wire 122z are connected to each other and the wire 123z and the wire 123a are connected to each other to transmit a communication data signal, their connection methods are arbitrary. In other words, they may be connected to each other by radio, light, or the like as well as connection by wires.

Furthermore, the transmission signal generated by the transmission signal generation unit 197 is transmitted to the signal smoothing device 106 of the temperature control device 109 via the terminal 112 through the wire 122a and a wire 122b.

The signal smoothing device 106 performs smoothing processing on the transmission signal transmitted from the processing device 101. The signal after the smoothing processing is transmitted to the drive device 104.

The signal smoothing device 106 does not necessarily need to have a function of communicating with the processing device 101. For example, a lowpass filter using a resistor and a capacitor can be used as the signal smoothing device 106.

The drive device 104 compares the signal transmitted from the signal smoothing device 106 with a predetermined reference voltage value. When a voltage value after the smoothing processing exceeds the reference voltage value, the drive device 104 applies a drive voltage to the temperature adjusting device 105.

The temperature adjusting device 105 is driven by the drive voltage transmitted from the drive device 104 and produces a temperature adjusting output to the arithmetic device 102 included in the processing device 101 and installed near the temperature adjusting device 105 to adjust a temperature of the arithmetic device 102. Herein, the arithmetic device 102 of the processing device 101 may be adjacent to the temperature adjusting device 105 or surrounded by the temperature adjusting device 105.

The processing device 101 or the arithmetic device 102 is, for example, a CPU or a microprocessor.

The drive device 104 is, for example, an amplifier, a differential amplifier, or a comparator.

The temperature adjusting device 105 is, for example, a cooling fan or a thermoelectric transducer such as a Peltier element. When the temperature adjusting device 105 is a cooling fan, the temperature adjusting output is a wind transmitted to the arithmetic device 102. When the temperature adjusting device 105 is a thermoelectric transducer, the temperature adjusting output is a temperature at which the thermoelectric transducer affects the arithmetic device 102.

Note that a temperature measuring device connected to the arithmetic device 102, which is not illustrated, can be installed near the arithmetic device 102 and monitor a temperature of the arithmetic device 102. In this case, the arithmetic device 102 can cause the temperature control signal generation unit 195 to adjust a temperature control signal being generated depending on the monitored temperature such that the temperature control signal is set to, for example, a signal for further intensifying cooling when the monitored temperature is high.

### [Signal Processing]

In the processing system 191, the transmission signal transmitted from the processing device 101 to the arithmetic device 003 is transmitted to the arithmetic device 003 through the wires 122a, 122c, 122z and is also transmitted to the signal smoothing device 106 through the wire 122b.

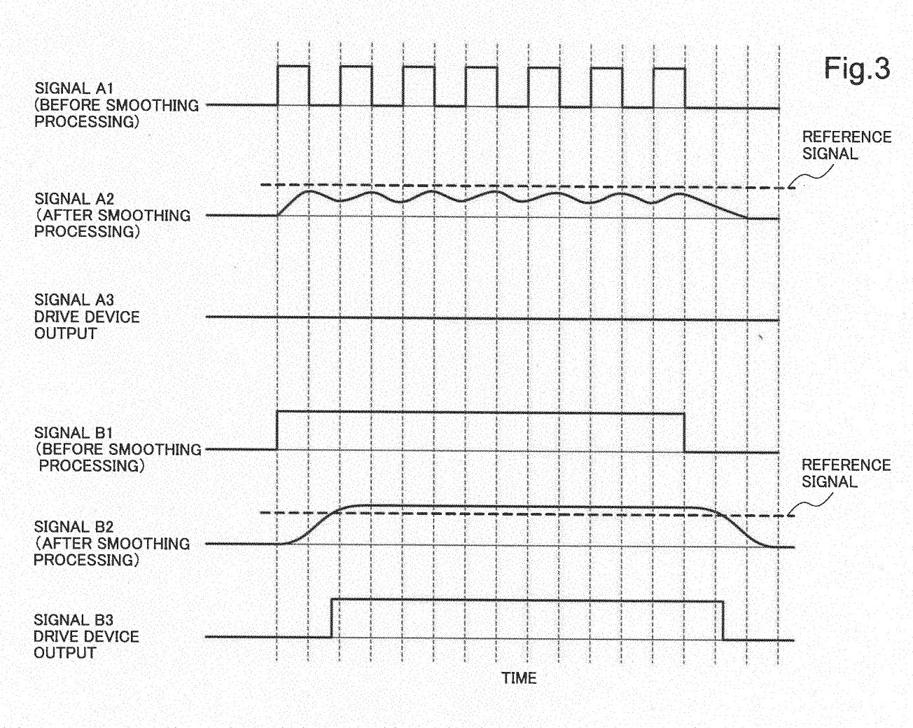

FIG. 3 is an image diagram illustrating signal processing in the signal smoothing device 106 and the drive device 104 in the processing system illustrated in FIG. 2.

Herein, it is assumed that a signal A1 being a communication data signal included in a transmission signal and a temperature control signal B1 included in the transmission signal are each input to the signal smoothing device 106 illustrated in FIG. 2. A signal A2 is an output from the signal smoothing device 106 to the drive device 104 when the signal A1 is input to the signal smoothing device 106. A signal B2 is an output from the signal smoothing device 106 to the drive device 104 when the signal B1 is input to the signal smoothing device 106. A signal A3 is an output from the drive device 104 when the signal A2 is input to the drive device 104. A signal B3 is an output from the drive device 104 when the signal B2 is input to the drive device 104.

As illustrated in FIG. 3, the signal A1 and the signal B1 are converted to the signal A2 and the signal B2 that gradually rise and fall by signal smoothing processing in the signal smoothing device 106.

The communication data signal A1 in particular has voltage switched between a high level and a low level in a short time. Accordingly, a state in which voltage of the signal A2 does not reach the maximum continues.

On the other hand, the temperature control signal remains at the same voltage level for a long time in comparison with the communication data signal. Accordingly, a state at the maximum voltage level or a voltage level close to the maximum continues for a long time, as illustrated by the signal B2 in FIG. 3.

As described above, it is assumed that the drive device 104 is set such that the drive device 104 produces a positive output when an input voltage is greater than a reference voltage. In this case, when the reference voltage is set as illustrated in FIG. 3, the signal A3 is zero and the signal B3 is an output for a long time as illustrated in FIG. 3.

When the signal A1 remains at either a low level or a high level for a long period of time, there is a possibility that the signal A2 may reach the maximum voltage and an output from the drive device 104 may become unstable. However, such a case is rare and it is assumed that an influence is usually small.

As described above, the processing system 191 illustrated in FIG. 2 performs the smoothing processing being high-frequency cutoff processing of allowing a low frequency to pass on the signal A1 and the signal B1 being input signals input to the drive device 104. Thus, drive voltages A3 and B3 subjected to the high-frequency cutoff processing of allowing a low frequency to pass can be obtained as outputs of the drive device 104. When the temperature adjusting device 105 is driven by these drive voltages subjected to the high-frequency cutoff processing of allowing a low frequency to pass, a temperature adjusting output from the temperature adjusting device 105 is subjected to the high-frequency cutoff processing of allowing a low frequency to pass.

Furthermore, in the processing system 191, the transmission signal is transmitted to the drive device 104 through the wires 122a and 122b, and is also transmitted to the arithmetic device 003 through the wires 122c and 122z. Thus, the arithmetic device 003 may perform reception processing on a temperature control signal included in the transmission signal as a communication data signal.

To prevent the reception processing, for example, a rule for specifying a temperature control signal may be defined between the processing device 101 and the arithmetic device 003. For example, a start signal indicating a start of a signal transmitted to the drive device 104 and an end signal indicating its end are defined between the processing device 101 and the arithmetic device 003. When determining that the arithmetic device 003 receives the start signal, the arithmetic device 003 determines that a subsequent signal other than the end signal is not a communication data signal addressed to the arithmetic device 003 and disposes of or ignores the subsequent signal. Then, when determining that the arithmetic device 003 receives the end signal, the arithmetic device 003 determines that a subsequent signal is a communication data signal addressed to the arithmetic device 003 and performs the reception processing.

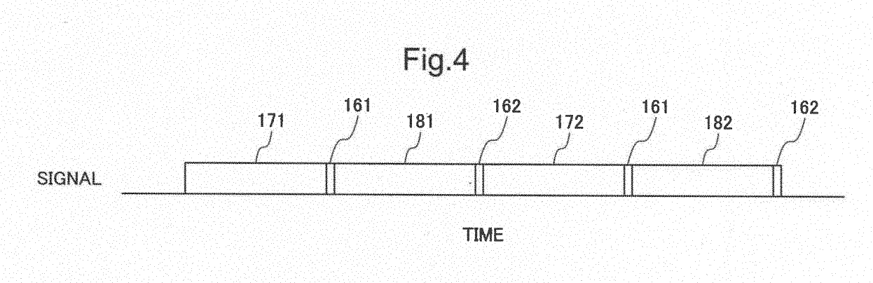

FIG. 4 is a conceptual diagram illustrating an example of a transmission signal transmitted from the terminal 112 of the processing device 101.

In the example illustrated in FIG. 4, a communication data signal 171, a start signal 161, a temperature control signal 181, an end signal 162, a communication data signal 172, a start signal 161, a temperature control signal 182, and an end signal 162 are transmitted in order as time progresses.

The example illustrates that a group of a communication data signal, a start signal, a temperature control signal, and an end signal is arranged one after the other, but the arrangement of the group of a communication data signal, a start signal, a temperature control signal, and an end signal is arbitrary. For example, with few communication data signals, an operation of inserting a group of a start signal, a temperature control signal, and an end signal can be performed.

For example, a universal asynchronous receiver transmitter (UART) disclosed in NPL 2 can be used as a specific protocol for the signals illustrated in FIG. 4.

### [Effects]

The processing system in the present example embodiment generates a transmission signal obtained by superimposing a communication data signal used in communication with another arithmetic device other than the arithmetic device of the processing system and a temperature control signal to be transmitted to the temperature control device. Then, the generated transmission signal is transmitted to the other arithmetic device and the temperature control device.

Furthermore, the temperature control device performs high-frequency cutoff processing of allowing a low frequency to pass on an input signal being input. In this way, when the input signal is a data signal of a high frequency, the processing system in the present example embodiment can reduce an influence of the data signal on a temperature adjusting output.

When a signal transmitted to another arithmetic device other than the arithmetic device of the processing device is a temperature control signal, the processing system in the present example embodiment adds a start signal and an end signal causing the other device to recognize that the signal is the temperature control signal. Thus, an influence on reception of the temperature control signal by the other device can be reduced.

As described above, the processing system in the present example embodiment can reduce the number of sending units (terminals) of the processing device included in the processing system. The reduction can be achieved with both communication between the processing device and another arithmetic device other than the arithmetic device of the processing device and temperature adjustment of at least part of the processing device.

### Second Example Embodiment

The present example embodiment is an example embodiment about a processing system of the present invention when respectively using a thermoelectric transducer and a comparator for a temperature adjusting device and a drive device.

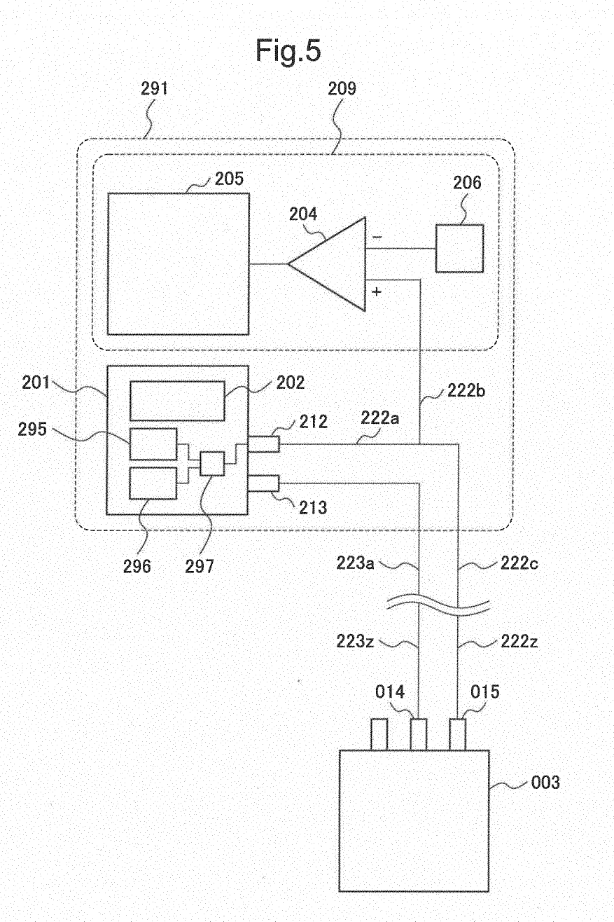

FIG. 5 is a conceptual diagram illustrating a configuration of a processing system in the present example embodiment.

A processing system 291 includes a processing device 201 and a temperature control device 209.

The temperature control device 209 is a temperature control means for controlling a temperature of at least part of the processing device 201, and includes a drive device 204, a temperature adjusting device 205, and a voltage application device 206.

The processing device 201 includes an arithmetic device 202, a temperature control signal generation unit 295, a data signal generation unit 296, a transmission signal generation unit 297, a terminal 212, and a terminal 213.

The temperature control signal generation unit 295 generates a temperature control signal for controlling the temperature control device 209. The generated temperature control signal is transmitted to the transmission signal generation unit 297.

The data signal generation unit 296 generates a communication data signal to be transmitted to an arithmetic device 003. The generated communication data signal is transmitted to the transmission signal generation unit 297.

The transmission signal generation unit 297 generates a transmission signal obtained by superimposing the temperature control signal transmitted from the temperature control signal generation unit 295 and the communication data signal transmitted from the data signal generation unit 296.

The transmission signal generated by the transmission signal generation unit 297 is transmitted to the arithmetic device 003 via the terminal 212 through wires 222a, 222c, and 222z via a terminal 015. The processing device 201 can receive a communication data signal transmitted from the arithmetic device 003 via a terminal 014 through wires 223z, 223a via the terminal 213. As described above, the processing device 201 can communicate with the arithmetic device 003.

Note that as long as the wire 222c and the wire 222z are connected to each other and the wire 223z and the wire 223a are connected to each other to transmit a communication data signal, their connection methods are arbitrary. In other words, they may be connected to each other by radio, light, or the like as well as connection by wires.

Furthermore, the transmission signal generated by the transmission signal generation unit 297 is transmitted to the drive device 204 via the terminal 212 through the wire 222a and a wire 222b.

The drive device 204 is a comparator. A signal transmitted from the processing device 201 is input to a non-inversion input terminal (an input terminal indicated by + in FIG. 5) of the drive device 204. On the other hand, a reference voltage is input from the voltage application device 206 to an inversion input terminal (an input terminal indicated by − in FIG. 5).

When a voltage input to the non-inversion input terminal is greater than a voltage input to the inversion input terminal, the drive device 204 outputs a predetermined positive voltage from its output terminal to the temperature adjusting device 205.

The temperature adjusting device 205 is a thermoelectric transducer. The temperature adjusting device 205 is driven by a drive voltage transmitted from the drive device 204 and performs temperature adjustment of the arithmetic device 202 included in the processing device 201 and installed near the temperature adjusting device 205. The temperature adjustment is typically cooling in terms of enhanced processing speed in the arithmetic device 202, but the temperature adjustment may be heating for adjusting processing speed in the arithmetic device 202 to be low, and the like. The arithmetic device 202 included in the processing device 201 may be adjacent to the temperature adjusting device 205 or surrounded by the temperature adjusting device 205.

The temperature adjusting device 205 switches whether the temperature adjustment is heating or cooling of the arithmetic device 202, depending on polarity of a voltage transmitted from the drive device 204.

The processing device 201 or the arithmetic device 202 is, for example, a CPU or a microprocessor.

For example, a battery generating a predetermined voltage can be used as the voltage application device 206.

Note that a temperature measuring device connected to the arithmetic device 202, which is not illustrated, can be installed near the arithmetic device 202 and monitor a temperature of the arithmetic device 202. In this case, the arithmetic device 202 can cause the temperature control signal generation unit 295 to adjust a temperature control signal being generated depending on the monitored temperature such that the temperature control signal is set to, for example, a signal for further intensifying cooling when the monitored temperature is high.

For example, a Peltier element can be used as the thermoelectric transducer being the temperature adjusting device 205.

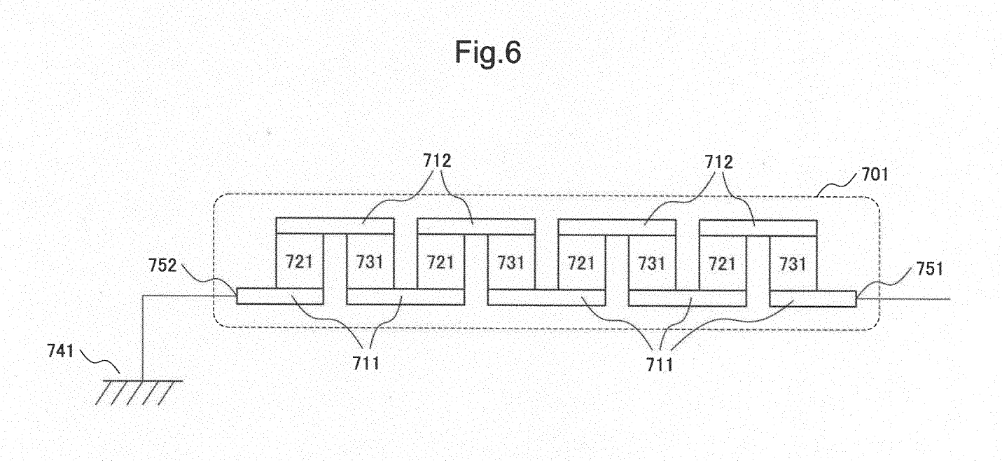

FIG. 6 is an image diagram illustrating an example of a section of a Peltier element.

As illustrated in FIG. 6, a Peltier element 701 exemplified in FIG. 6 includes five lower conductors 711, four upper conductors 712, four P-type semiconductors 721 that each connect the corresponding lower conductor 711 and upper conductor 712, and four N-type semiconductors 731 that each connect the corresponding lower conductor 711 and upper conductor 712. As illustrated in FIG. 6, the P-type semiconductors 721 and the N-type semiconductors 731 are alternately disposed in a transverse cross-sectional direction.

One end portion 751 of the Peltier element 701 is connected to a drive device, which is not illustrated, and another end portion 752 is connected to a ground 741.

As is well known, in the Peltier element 701, the lower conductors 711 are cooled and the upper conductors 712 are heated when a value of a voltage applied to the end portion 751 is negative. In the Peltier element 701, the lower conductors 711 are heated and the upper conductors 712 are cooled when a value of a voltage applied to the end portion 751 is positive.

Therefore, when the Peltier element 701 is placed on a processing device or an arithmetic device, for example, the processing device or the arithmetic device can be heated or cooled by switching between positive and negative of a voltage applied to the end portion 751.

FIG. 6 illustrates four pairs of the N-type semiconductors 731 and the P-type semiconductors 721 adjacent to each other, but the number of pairs is arbitrary.

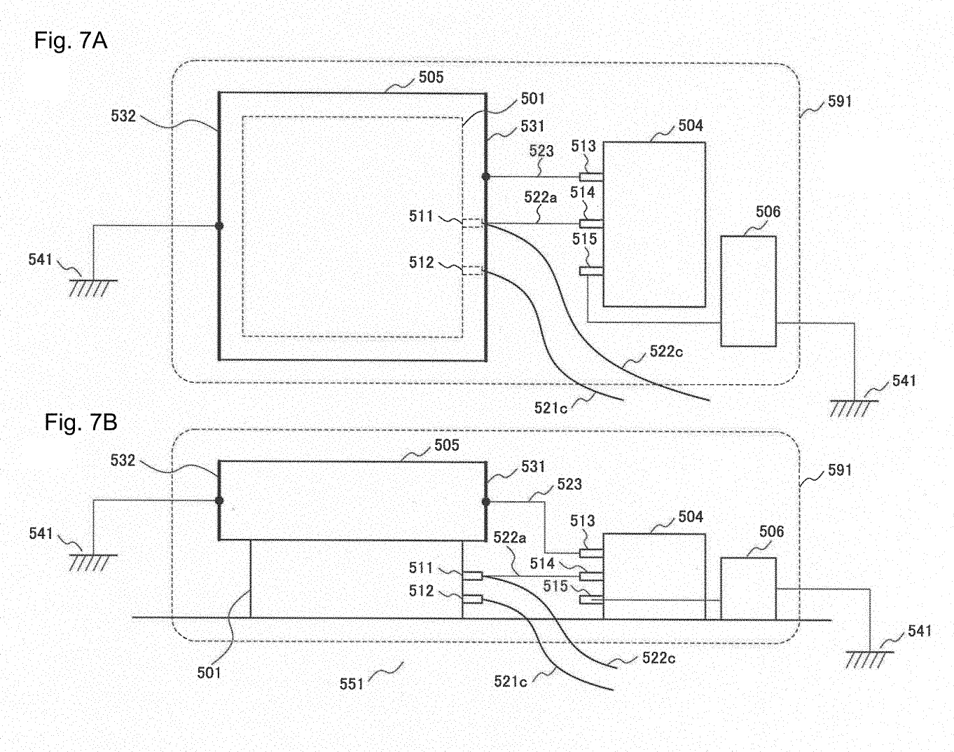

FIG. 7 is an image diagram illustrating an example of the processing system in the present example embodiment when the Peltier element illustrated in FIG. 6 is placed on a processing device. In FIG. 7, (a) and (b) respectively illustrate a top view and a cross-sectional view.

A processing system 591 includes a Peltier element 505, a processing device 501, a comparator 504, and a voltage application device 506, and is formed on a base substrate 551.

The processing device 501 includes an arithmetic device, which is not illustrated.

The Peltier element 505 is placed on top of the processing device 501 such that a lower surface of the Peltier element 505 is adjacent to the processing device 501.

The processing device 501 can transmit a transmission signal including a communication data signal to another arithmetic device different from the arithmetic device mentioned above, which is not illustrated, via a terminal 511 through a wire 522c.

The processing device 501 can transmit a transmission signal including a temperature adjusting signal to a terminal 514 being a non-inversion input terminal of the comparator 504 via the terminal 511 through a wire 522a.

A reference voltage is applied from the voltage application device 506 to a terminal 515 being an inversion input terminal of the comparator 504.

The processing device 501 also can receive a communication data signal transmitted from the other arithmetic device through a wire 521c via a terminal 512.

When the terminal 514 receives a signal, the comparator 504 applies a voltage corresponding to a voltage of the received signal to an end portion 531 of the Peltier element 505 via a terminal 513 being an output terminal through a wire 523. Another end portion 532 of the Peltier element 505 is connected to a ground 541. In this way, the lower surface of the Peltier element 505 is heated or cooled. Accordingly, the processing device 501 is heated or cooled, and temperature adjustment is performed on the processing device 501.

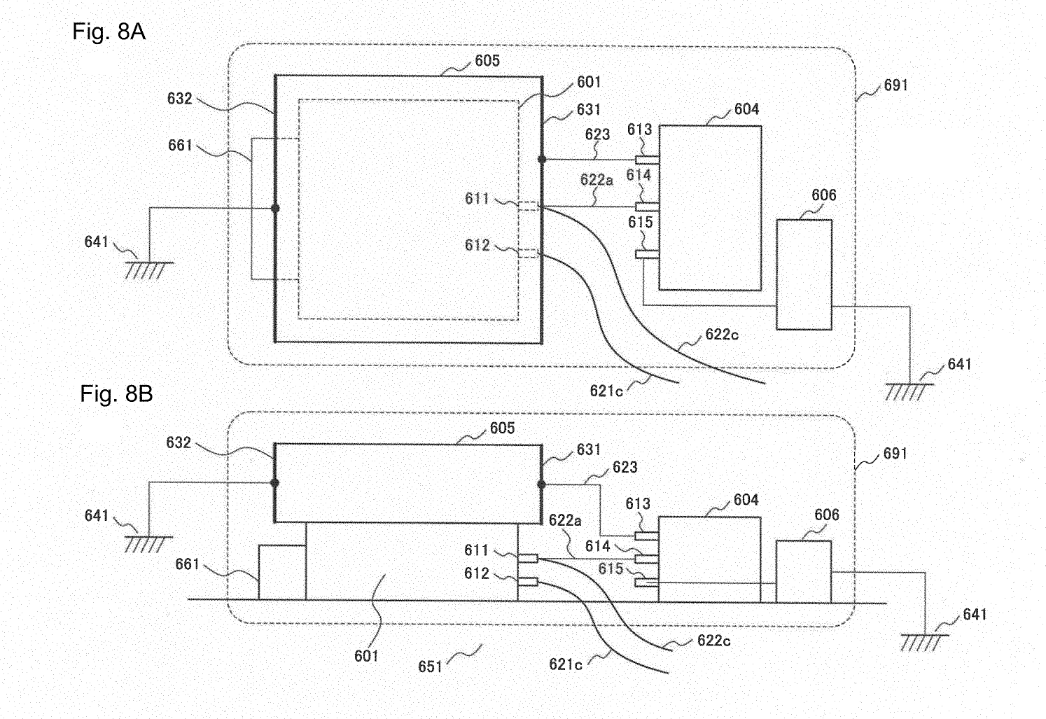

FIG. 8 is an image diagram illustrating a processing system 691 including a temperature detecting device for detecting a temperature of a processing device.

A configuration of the processing system 691 is different from the configuration of the processing system 591 illustrated in FIG. 7 only in that a temperature sensor 661 is added.

The temperature sensor 661 is located near a processing device 601 and transmits a signal including information about a measured temperature to the processing device 601 through a signal path, which is not illustrated.

The processing device 601 adjusts a temperature adjusting signal transmitted to a comparator 604 on the basis of the information about a measured temperature by the temperature sensor 661. For example, when a temperature detected by the temperature sensor 661 is higher than a preset reference temperature, the processing device 601 transmits a temperature control signal for causing a Peltier element 605 to increase time for cooling the processing device 601 to the comparator 604.

The description of each configuration of the processing system 691 is the same as the description of the processing system 591 illustrated in FIG. 7 except for the description above. However, when the hundreds digit is 5 in the number included in a reference numeral of each component in the description, the hundreds digit is replaced with 6 for reference.

### [Signal Processing]

Hereinafter, signal processing in the processing system in the present example embodiment will be described by taking the signal processing in the processing system 291 illustrated in FIG. 5 as an example. In the processing system 291, a communication data signal transmitted from the processing device 201 to the arithmetic device 203 is transmitted to the arithmetic device 003 through the wires 222a, 222c, 222z and is also transmitted to the drive device 104 through the wire 222b.

In this regard, in a case of the processing system 291, a proportion (hereinafter referred to as a mark ratio) of time during which a signal voltage is applied to a total of time during which a signal voltage is applied and time during which no signal voltage is applied is set to be almost half in a communication data signal. Thus, an influence of a communication data signal on temperature controlled by the temperature control device 206 can be reduced.

As described above, when a signal voltage input to a non-inversion input terminal is greater than a reference voltage input to an inversion input terminal, the drive device being the comparator outputs a positive drive voltage. The voltage input to the non-inversion input terminal is greater than the reference voltage during the application of the signal voltage, so that an output from the drive device is positive. In this case, a thermoelectric transducer receives an input of a positive voltage, and a conductor closer to the processing device or the arithmetic device is cooled (or heated).

On the other hand, when a signal voltage input to the non-inversion input terminal is smaller than the reference voltage input to the inversion input terminal, a negative voltage is output. The voltage input to the non-inversion input terminal is smaller than the reference voltage during no application of the signal voltage, so that an output from the drive device is negative. In this case, the thermoelectric transducer receives an input of a negative voltage, and the conductor closer to the processing device or the arithmetic device is heated (or cooled).

As described above, if the mark ratio is half in the communication data signal, a ratio of heating time and cooling time is equal, more specifically, neither heating nor cooling is performed by averaging the heating time and the cooling time.

When the ratio of the time during which the signal voltage is applied and the time during which no signal voltage is applied is simply equal, a temperature changes due to heating and cooling for a period of heating time and a period of cooling time even if neither heating nor cooling is performed by averaging the heating time and the cooling time. However, as described above, application and non-application of the signal voltage are switched in a short time, so that even if heating occurs, cooling occurs before a temperature nearly increases. As a result, a temperature hardly changes.

The reason is that when the thermoelectric transducer converts an input drive voltage to a temperature being a temperature adjusting output of the thermoelectric transducer, smoothing processing is performed on the temperature being the temperature adjusting output.

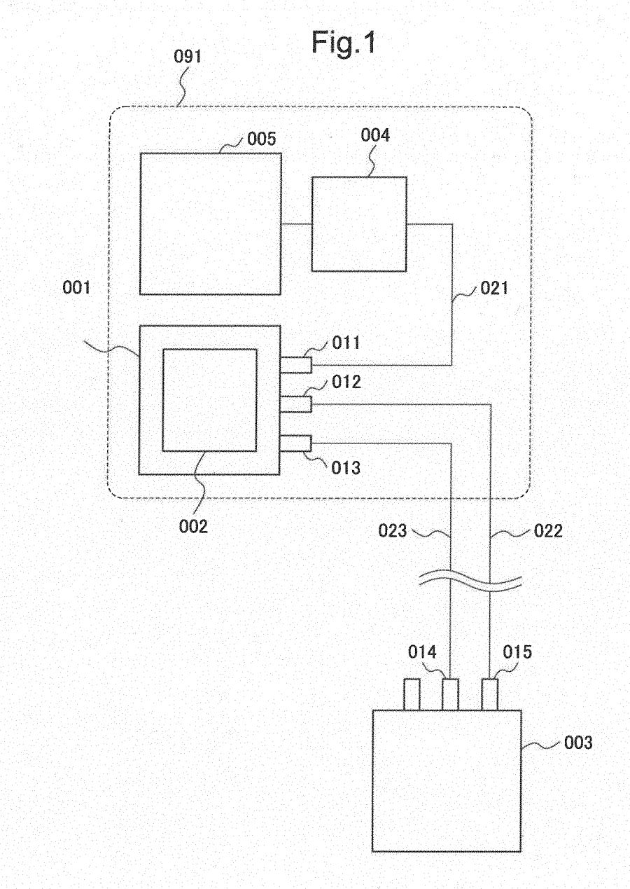

When the mark ratio is significantly deviated from half, a measure is taken to prevent the ratio from being significantly different. For such a measure, the ratio may be set to be almost equal by limiting the use of a character code causing the mark ratio to be greatly deviated from half or by performing a protocol conversion, such as scrambling, on a communication data signal. For example, Frame Synchronization Scrambler (configuration example) in FIG. 1.16 or the like in NPL 1 describes scrambling on a communication data signal.

In this way, in the processing system 291 illustrated in FIG. 5, the mark ratio in the communication data signal transmitted from the processing device 201 to the arithmetic device 003 is set to be almost half, and the temperature control device 209 performs the actions described above.

The description of the signal processing is the same as the description of the signal processing in the first example embodiment except for the description above. However, when the hundreds digit is 1 in the number in the reference numerals indicating the configurations in the description of the signal processing in the first example embodiment, the hundreds digit is replaced with 2 for reference.

### [Effects]

The processing system in the present example embodiment has the same effects as those of the processing system in the first example embodiment.

In addition, the processing system in the present example embodiment respectively uses the comparator configured to compare the magnitude of a reference voltage and an input signal and produce an output and the thermoelectric transducer for the drive device and the temperature adjusting device. Then, a mark ratio in a communication data signal input to the drive device is set to be almost half. The almost half mark ratio input to the drive device results in an almost half mark ratio in a drive voltage input from the drive device to the thermoelectric transducer. The thermoelectric transducer performs smoothing processing when converting the input drive voltage to a temperature adjusting output by the property of delaying an output with respect to an input. Thus, a temperature decreases before the temperature nearly increases, and a temperature increases before the temperature nearly decreases. Furthermore, because the mark ratio in the drive voltage input to the thermoelectric transducer is almost half, a cooling amount and a heating amount in a temperature adjusting output portion of the thermoelectric transducer are equal, and, as a result, do not change by averaging time of temperatures of the temperature adjusting output portion.

In this way, the thermoelectric transducer can therefore reduce an influence of an input of a communication data to the drive device on a temperature adjusting output.

Thus, a signal smoothing device, which is provided in the temperature control device in the first example embodiment and is on a prior stage of the drive device, can be omitted from the processing system in the present example embodiment. The number of parts constituting the processing system in the present example embodiment can be reduced.

### Third Example Embodiment

The present example embodiment is an example embodiment about a processing system in which a processing device transmits a temperature adjusting signal while receiving a communication data signal from an arithmetic device other than the arithmetic device of the processing device.

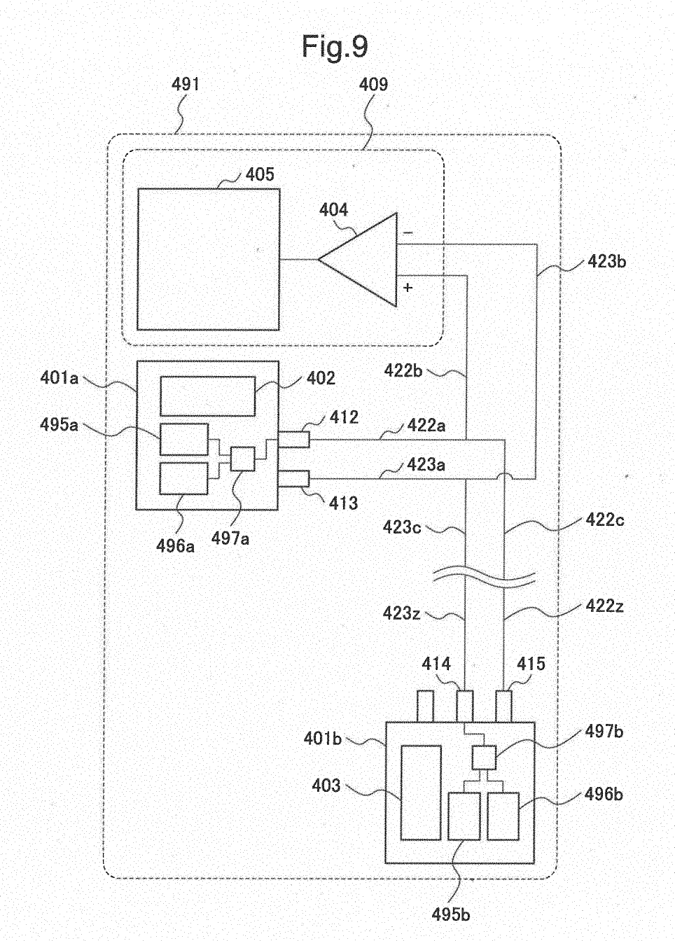

FIG. 9 is a conceptual diagram illustrating a configuration of a processing system 491 in the present example embodiment.

The processing system 491 includes a processing device 401a, a temperature control device 409, and a processing device 401b.

The temperature control device 409 is a temperature control means for controlling a temperature of at least part of the processing device 401a, and includes a drive device 404 and a temperature adjusting device 405.

The processing device 401a includes an arithmetic device 402, a temperature control signal generation unit 495a, a data signal generation unit 496a, a transmission signal generation unit 497a, a terminal 412, and a terminal 413.

The temperature control signal generation unit 495a generates a first temperature control signal for controlling the temperature control device 409. The generated first temperature control signal is transmitted to the transmission signal generation unit 497.

The data signal generation unit 496a generates a first communication data signal to be transmitted to the processing device 401a. The generated first communication data signal is transmitted to the transmission signal generation unit 497a.

The transmission signal generation unit 497a generates a first transmission signal obtained by superimposing the first temperature control signal transmitted from the temperature control signal generation unit 495a and the first communication data signal transmitted from the data signal generation unit 496a.

The processing device 401b includes an arithmetic device 403, a temperature control signal generation unit 495b, a data signal generation unit 496b, a transmission signal generation unit 497b, a terminal 414, and a terminal 415.

The temperature control signal generation unit 495b generates a second temperature control signal for controlling the temperature control device 409. The generated second temperature control signal is transmitted to the transmission signal generation unit 497b.

The data signal generation unit 496b generates a second communication data signal to be transmitted to the arithmetic device 003. The generated second communication data signal is transmitted to the transmission signal generation unit 497b.

The transmission signal generation unit 497b generates a second transmission signal obtained by superimposing the second temperature control signal transmitted from the temperature control signal generation unit 495b and the second communication data signal transmitted from the data signal generation unit 496b.

The first transmission signal generated by the transmission signal generation unit 497a is transmitted to the processing device 401b including the arithmetic device 403 via the terminal 412 through wires 422a, 422c, and 422z via the terminal 415.

The processing device 401a can receive the second transmission signal including the second communication data signal transmitted from the processing device 401b via the terminal 414 through wires 423z, 423c, and 423a via the terminal 413. As described above, the processing device 401a can communicate with the processing device 401b.

Note that as long as the wire 422c and the wire 422z are connected to each other and the wire 423z and the wire 423c are connected to each other to transmit a communication data signal, their connection methods are arbitrary. In other words, they may be connected to each other by radio, light, or the like as well as connection by wires.

The first transmission signal generated by the transmission signal generation unit 497a is also transmitted to a non-inversion input terminal (terminal indicated by + in FIG. 9) of the drive device 404 being a comparator through a wire 422b.

The second transmission signal transmitted to the processing device 401a via the terminal 414 is also transmitted to an inversion input terminal (terminal indicated by − in FIG. 9) of the drive device 404 being the comparator through a wire 423b.

Furthermore, the first transmission signal generated by the transmission signal generation unit 497a is transmitted to the drive device 404 via the terminal 412 through the wires 422a and 422b.

Furthermore, the second transmission signal generated by the transmission signal generation unit 497b is transmitted to the drive device 404 via the terminal 414 through the wires 423z, 423c, and 423b.

The drive device 404 outputs a positive voltage when a signal input to the non-inversion input terminal is greater than a signal input to the inversion input terminal. The drive device 404 outputs a negative voltage when a signal input to the non-inversion input terminal is smaller than a signal input to the inversion input terminal.

The output voltage output from the drive device 404 is transmitted to the temperature adjusting device 405.

The temperature adjusting device 405 is driven by a voltage transmitted from the drive device 404 and performs temperature adjustment of the arithmetic device 402 included in the processing device 401a and installed near the temperature adjusting device 405. Herein, the arithmetic device 402 of the processing device 401a may be adjacent to the temperature adjusting device 405 or surrounded by the temperature adjusting device 405.

The processing device 401a or the arithmetic device 402 is, for example, a CPU or a microprocessor.

The processing device 401b or the arithmetic device 403 is, for example, a CPU or a microprocessor.

The drive device 404 is a comparator.

The temperature adjusting device 405 is a thermoelectric transducer such as a Peltier element. The Peltier element may have the configuration described for FIG. 6, for example.

Note that a temperature measuring device connected to the arithmetic device 402, which is not illustrated, can be installed near the arithmetic device 402 and monitor a temperature of the arithmetic device 402. In this case, the arithmetic device 402 can cause the temperature control signal generation unit 495a to adjust the first temperature control signal being generated depending on the monitored temperature. Furthermore, the arithmetic device 402 communicates with the arithmetic device 403, and allows the arithmetic device 403 to cause the temperature control signal generation unit 495b to adjust the second temperature control signal being generated depending on the monitored temperature.

### [Signal Processing]

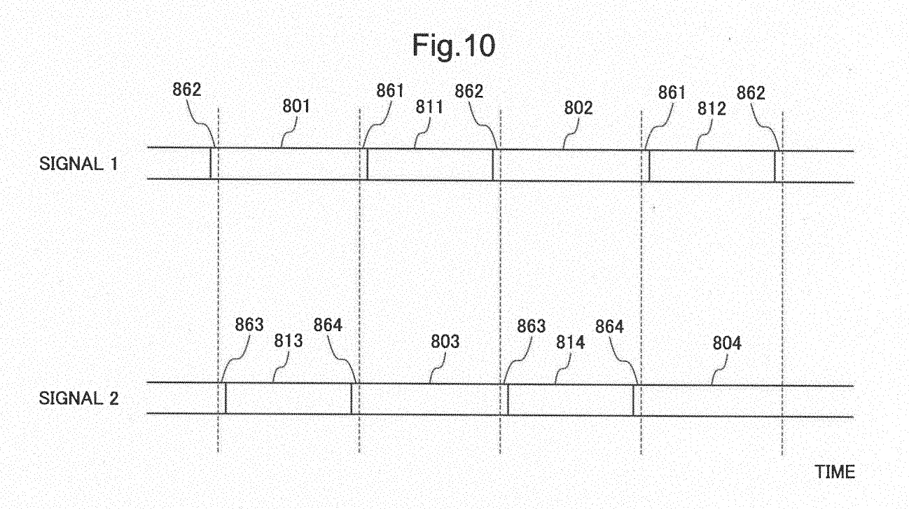

FIG. 10 is an image diagram illustrating an example of a signal input to the drive device 404 being the comparator. In FIG. 10, a signal 1 is an input signal input from the processing device 401a to the non-inversion input terminal (terminal indicated by “+” in FIG. 9) of the drive device 404 via the terminal 412 through 422a and 422b in the processing system illustrated in FIG. 9. The signal 1 is synchronized with an input to the non-inversion input terminal and is also input to the processing device 401b through the wires 423c and 423z and the terminal 414.

A signal 2 is an input signal input from the processing device 401b to the inversion input terminal (terminal indicated by “−” in FIG. 9) of the drive device 404 via the terminal 414 through 423z, 423c, and 423b. The signal 2 is synchronized with an input to the inversion input terminal and is also input to the processing device 401a via the wire 423a and the terminal 413.

As illustrated in FIG. 10, the signal 1 includes an end signal 862, a communication data signal 801, a start signal 861, a temperature control signal 811, an end signal 862, a communication data signal 802, a start signal 861, a temperature control signal 812, and an end signal 862 arranged in order as time progresses.

On the other hand, the signal 2 includes a start signal 863, a temperature control signal 813, an end signal 864, a communication data signal 803, a start signal 863, a temperature control signal 814, an end signal 864, and a communication data signal 804 arranged in order as time progresses.

Timing of the signal 1 and the signal 2 is as illustrated in FIG. 10. In other words, the end signal 862 is transmitted as the signal 1 immediately before the start signal 863 is transmitted as the signal 2, and the start signal 863, the temperature control signal 813, and the end signal 864 are transmitted as the signal 2 while the communication data signal 801 is transmitted as the signal 1. Furthermore, the communication data signal 803 is transmitted as the signal 2 while the start signal 861, the temperature control signal 811, and the end signal 862 are transmitted as the signal 1. Furthermore, the start signal 863, the temperature control signal 814, and the end signal 864 are transmitted as the signal 2 while the communication data signal 802 is transmitted as the signal 1. Furthermore, the communication data signal 804 is transmitted as the signal 2 while the start signal 861, the temperature control signal 812, and the end signal 862 are transmitted as the signal 1.

Herein, the start signal is a signal notifying a processing device on the other end of communication that a subsequent signal is a temperature control signal. The processing device that receives the start signal does not perform reception processing on a signal subsequent to the start signal as a communication data signal until the processing device subsequently receives the end signal.

The end signal is a signal notifying a processing device on the other end of communication that transmission of a temperature control signal is completed. The processing device that receives the end signal performs the reception processing on a received signal subsequent to the end signal as a communication data signal.

Note that the end signal 862 includes information specifying contents of a temperature control signal transmitted next from the processing device 408b illustrated in FIG. 9 that receives the end signal 862 to the drive device 404. The processing device 408b follows the specified contents and transmits the temperature control signals 813 and 814 to the drive device 404.

For example, a universal asynchronous receiver transmitter (UART) disclosed in NPL 2 can be used as a specific protocol for the signal 1 and the signal 2 illustrated in FIG. 10.

As illustrated in FIG. 10, the processing system 491 illustrated in FIG. 9 can transmit a temperature control signal to the drive device 404 while receiving a communication signal transmitted from a processing device on the other end of communication. Thus, the processing system 491 can further enhance a proportion of time for performing temperature control, and can therefore perform temperature control with higher precision.

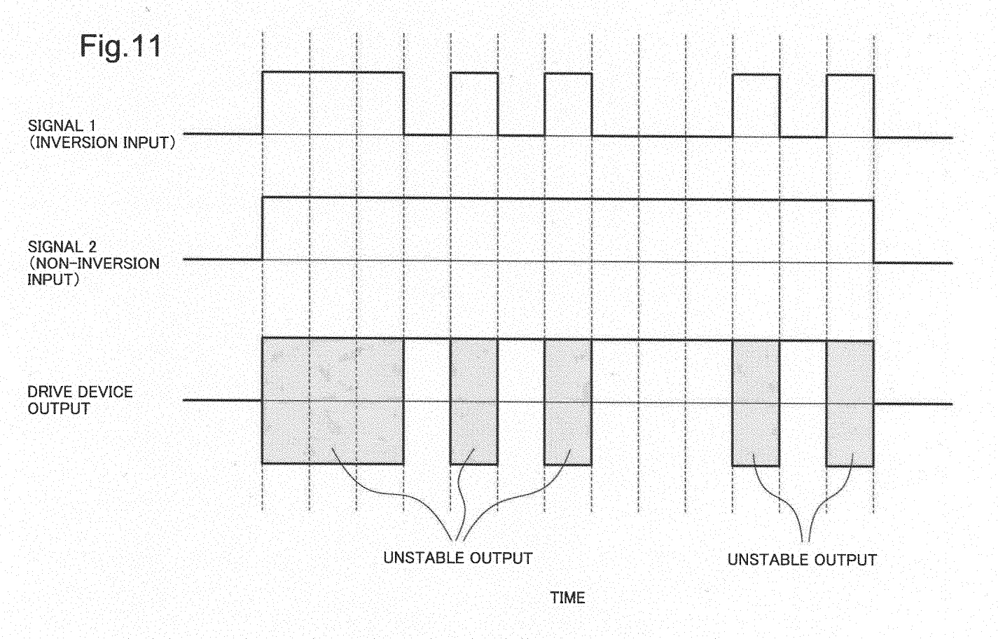

FIG. 11 is an image diagram illustrating an example of output of the drive device being the comparator when the signal 1 is a communication data signal and the signal 2 is a temperature control signal having DC voltage.

The drive device compares voltage levels of the communication data signal input to the inversion input terminal and the temperature control signal input to the non-inversion input terminal and produces an output illustrated as a drive device output in FIG. 11. However, it is assumed that response to an input and an output of the comparator is sufficiently early.

An output indicated by “unstable output” in FIG. 11 represents an output switched between a positive output and a negative output in an extremely short cycle, and it is assumed that an average value of the output is zero. In a time zone indicated by “unstable output” in FIG. 11, voltage values of signals input to the comparator are equal, so that positive and negative of the output are not fixed to one of them due to slight variations in an offset voltage, and such a phenomenon that positive and negative are switched in a short time may occur.

However, the thermoelectric transducer that inputs the output repeats heating and cooling in an extremely short time, so that a temperature does not change because cooling occurs before a temperature increases by heating and heating occurs before a temperature decreases by cooling.

The unstable output can be removed by installing a lowpass filter having an appropriate cutoff frequency on a subsequent stage of an output of the comparator, or the like. In this case, an output is zero in the time zone indicated by “unstable output” in FIG. 11.

As described above, when the start signal is inserted before the temperature control signal and is input to the drive device 404, the drive device 404 compares the magnitude of voltage levels of the start signal and the communication data signal and produces an output. The output may not necessarily be a temperature in a direction desired to be adjusted. However, the start signal is only for indicating a start of the temperature control signal, so that the start signal can be a signal for a short time. In this way, an influence of the output on a temperature of the temperature adjusting device 405 can be negligible.

When the end signal is inserted after the temperature control signal and is input to the drive device 404, the drive device 404 compares the magnitude of voltage levels of the end signal and the communication data signal and produces an output. The output may not necessarily be a temperature in a direction desired to be adjusted. However, the end signal is only for indicating an end of the temperature control signal and specifying a temperature control signal transmitted from a processing device on the other end to the drive device 404, so that the end signal can be a signal for a short time. In this way, an influence of the output on a temperature of the temperature adjusting device 405 can be negligible.

When the processing system illustrated in FIG. 9 inputs the signal 1 and the signal 2 as illustrated in FIG. 11 to the drive device, an output (except for “unstable output”) is produced from the drive device 404 only while the communication data signal being the signal 1 is at a low level. This also occurs even when the signal 2 is continuously input as illustrated in FIG. 11. Thus, when there is a request to produce an output (except for “unstable output”) for a long time from the drive device 404, the processing system cannot respond to the request.

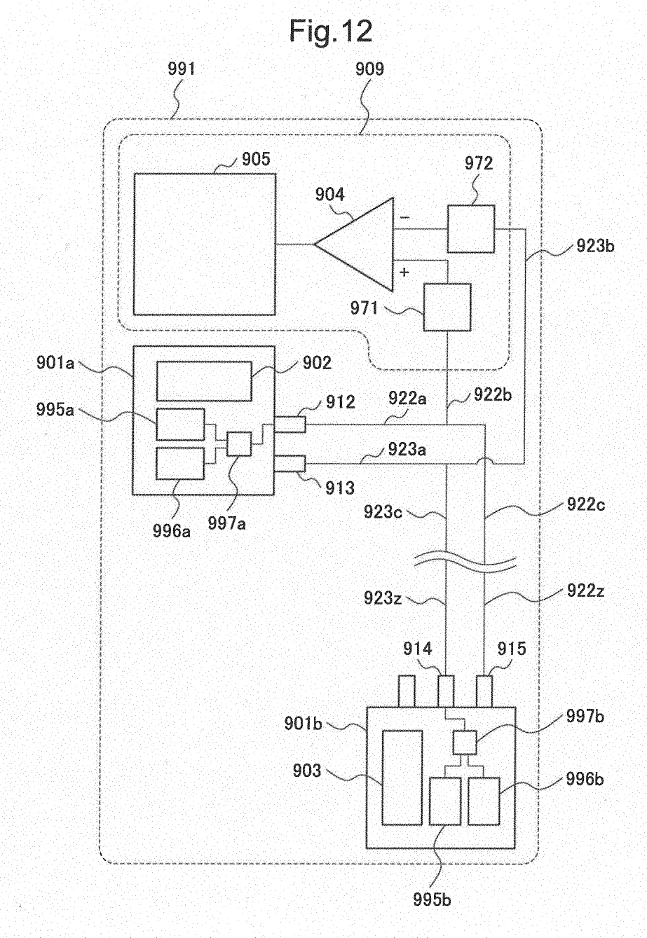

FIG. 12 is a conceptual diagram illustrating a configuration of a processing system 991 in the present example embodiment that may solve the above-mentioned problems.

The processing system 991 includes a processing device 901a, a temperature control device 909, and a processing device 901b.

The temperature control device 909 is a temperature control means for controlling a temperature of at least part of the processing device 901a, and includes a drive device 904, a temperature adjusting device 905, a signal smoothing device 971, and a signal smoothing device 972.

The processing system 991 is different from the processing system 491 illustrated in FIG. 9 in that the signal smoothing device 971 is inserted between a wire 922b and a non-inversion input terminal of the drive device 904. The processing system 991 is also different from the processing system 491 illustrated in FIG. 9 in that the signal smoothing device 972 is inserted between a wire 923b and an inversion input terminal of the drive device 904. The differences in configuration between the processing system 991 and the processing system 491 illustrated in FIG. 9 are only the two points described above.

The description of each configuration of the processing system 991 is the same as the description of the processing system 491 illustrated in FIG. 9 except for the description below. However, when the hundreds digit is 4 in the reference numeral indicating each configuration in the description, the hundreds digit is replaced with 9.

A first transmission signal transmitted from the processing device 901a to the processing device 901b is also transmitted to the signal smoothing device 971 through the wire 422b. The signal smoothing device 971 performs signal smoothing on the transmitted first transmission signal and transmits it to the non-inversion input terminal of the drive device 904 being a comparator. The signal smoothing performed by the signal smoothing devices 971 and 972 can be achieved by performing processing of making rising and falling of a signal gradual, which is often performed in general, on an input signal. The signal smoothing devices 971 and 972 do not necessarily need to have a function of communicating with the processing devices 901a and 901b. For example, a lowpass filter using a resistor and a capacitor can be used as the signal smoothing devices 971 and 972.

The second transmission signal transmitted from the processing device 901b to the processing device 901a is also transmitted to the signal smoothing device 972 through the wire 923b. The signal smoothing device 972 performs signal smoothing on the transmitted second transmission signal and transmits it to the inversion input terminal of the drive device 904 being the comparator.

### [Signal Processing]

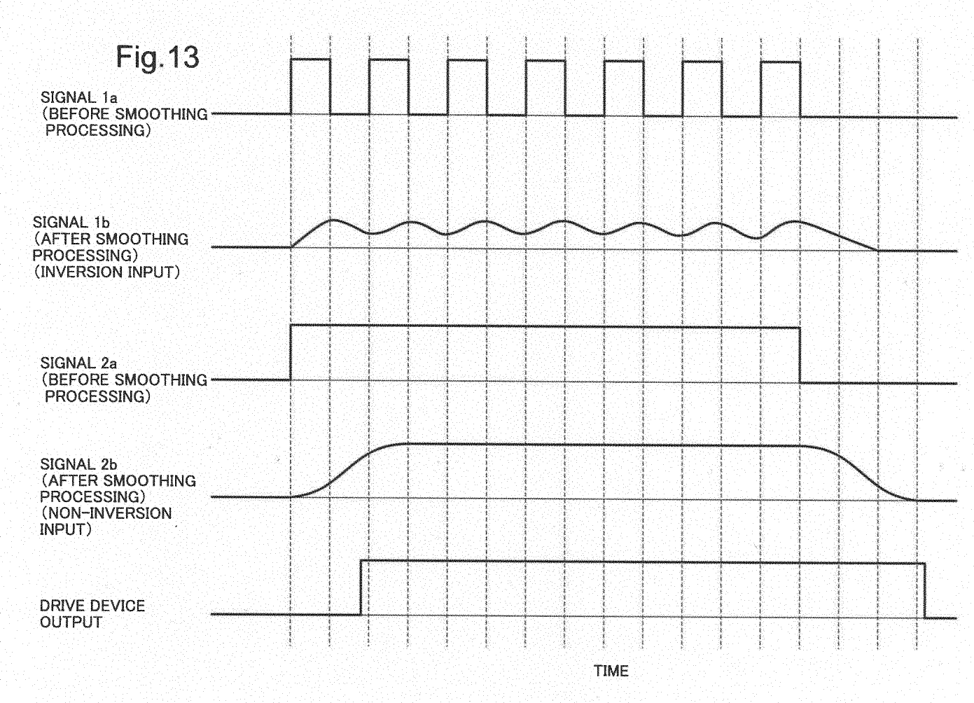

FIG. 13 is an image diagram illustrating signal processing in the signal smoothing devices and the drive device 904 in the processing system illustrated in FIG. 12.

Herein, it is assumed that a signal 1a being a communication data signal and a signal 2a being a temperature control signal are respectively input to the signal smoothing device 971 and the signal smoothing device 972 illustrated in FIG. 12. A signal 1b illustrated in FIG. 13 is an output from the signal smoothing device 971 to a non-inversion input of the drive device 904, and a signal 2b illustrated in FIG. 13 is an output from the signal smoothing device 972 to an inversion input of the drive device 904. A drive device output is a drive voltage output from the drive device 904.

The signal 1a and the signal 2a are converted to the signal 1b and the signal 2b that gradually rise and fall by the signal smoothing processing in the signal smoothing devices 971 and 972 as illustrated in FIG. 13.

The communication data signal 1a in particular has voltage switched between a high level and a low level in a short time. Accordingly, a state in which voltage of the signal 1b does not reach the maximum continues.

On the other hand, the temperature control signal remains at the same voltage level for a long time in comparison with the communication data signal. Accordingly, a state at the maximum voltage level or a voltage level close to the maximum continues for a long time, as illustrated by the signal 2b in FIG. 13.

The drive device 904 being the comparator outputs a positive voltage when the signal 2b is greater than the signal 1a, and thus produces an output for a long time, as illustrated by the drive device output in FIG. 13.

When the signal 1a remains at either a low level or a high level for a long period of time, there is a possibility that the signal 1b may reach the maximum voltage and an output from the drive device 904 may become unstable. However, such a case is rare and it is assumed that an influence is usually small.

As described above, the processing system 991 illustrated in FIG. 12 can continuously produce an output for a long time by the drive device, which cannot be achieved by the processing system 491 illustrated in FIG. 9.

### [Effects]

The processing system in the present example embodiment first has the same effects as those of the processing system in the first example embodiment.

In the processing system in the present example embodiment, when the processing device does not transmit a temperature control signal to the drive device, a processing device on the other end of communication with the processing device transmits a temperature control signal to the drive device.

Thus, the processing system in the present example embodiment can further enhance a proportion of time for performing temperature control, and can therefore perform temperature control on the processing device with higher precision.

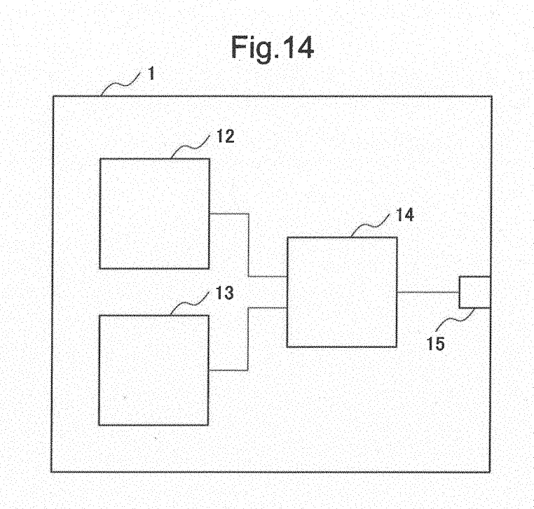

A conceptual diagram illustrating a configuration of a processing device 1 having the smallest configuration of the present invention is illustrated in FIG. 14.

The processing device 1 includes a temperature control signal generation unit 12, a data signal generation unit 13, a transmission signal generation unit 14, and a sending unit 15.

The temperature control signal generation unit 12 generates a temperature control signal to be transmitted to a temperature control means, which has identification information attached thereto for allowing another device communicating with the processing device other than the temperature control means to identify the temperature control signal.

Herein, the temperature control means is a means for performing a temperature adjusting output on at least part of the processing device. In a process of converting an input signal input to the temperature control means to the temperature adjusting output, the temperature control means performs high-frequency cutoff processing of allowing a low frequency to pass on at least one of the input signal and signal processed from the input signal.

The data signal generation unit 13 generates a communication data signal to be transmitted to the other device.

The transmission signal generation unit 14 generates a transmission signal obtained by superimposing the temperature control signal and the data signal.

The sending unit 15 sends the transmission signal to the temperature control means and the other device.

With the configuration above, an information processing method having the minimum configuration of the present invention has the effects described in [Advantageous Effects of Invention].

The whole or part of the example embodiments disclosed above can be described as, but not limited to, the following supplementary notes.

### (Supplementary Note A1)

A processing device including:

a temperature control signal generation unit configured to generate a temperature control signal that is to be transmitted to a temperature control means and that has identification information attached thereto for allowing another device communicating with the processing device other than the temperature control means to identify the temperature control signal, the temperature control means performing a temperature adjusting output on at least part of the processing device and performing, in a process of converting an input signal being input to the temperature adjusting output, high-frequency cutoff processing of allowing a low frequency to pass on at least one of the input signal and signal processed from the input signal;

a data signal generation unit configured to generate a communication data signal to be transmitted to the another device;

a transmission signal generation unit configured to generate a transmission signal obtained by superimposing the temperature control signal and the data signal; and a sending unit configured to send the transmission signal to the temperature control means and the another device.

### (Supplemental Note A2)

The processing device according to Supplementary Note A1, wherein the temperature control means includes a temperature adjusting means for performing the temperature adjusting output and a drive unit for driving the temperature adjusting means, and the drive unit applies a drive voltage to the temperature adjusting means.

### (Supplementary Note A3)

The processing device according to Supplementary Note A2, wherein the temperature adjusting means is a fan, and the temperature adjusting output is a wind sent to the at least part.

### (Supplementary Note A4)

The processing device according to Supplementary Note A2, wherein the temperature adjusting means is a thermoelectric transducer, and the temperature adjusting output is a temperature that affects the at least part.

### (Supplementary Note A5)

The processing device according to Supplementary Note A2 or A4, wherein the temperature adjusting means is a Peltier element, and the temperature adjusting output is a temperature that affects the at least part.

### (Supplementary Note A6)

The processing device according to any one of Supplementary Notes A1 to A5, wherein the high-frequency cutoff processing includes signal smoothing processing of performing signal smoothing by the temperature control means on a communication data signal input to the temperature control means.

### (Supplementary Note A7)

The processing device according to any one of Supplementary Notes A2 to A6, wherein the high-frequency cutoff processing includes signal smoothing processing of performing signal smoothing by the temperature control means on a communication data signal input to the temperature control means, in the drive unit or on a prior stage of an input to the drive unit.

### (Supplementary Note A8)

The processing device according to any one of Supplementary Notes A2 to A7, wherein the high-frequency cutoff processing includes smoothing processing of the temperature adjusting output performed by the temperature control means when the drive voltage is converted to the temperature adjusting output in the temperature adjusting means.

### (Supplementary Note A9)

The processing device according to any one of Supplementary Notes A1 to A8, wherein the high-frequency cutoff processing includes mark ratio equalizing processing of setting a mark ratio of the communication data signal of the processing device to substantially half.

### (Supplementary Note A10)

The processing device according to Supplementary Note A9, wherein the mark ratio equalizing processing includes processing of limiting inclusion of a character or a symbol being a signal causing a mark ratio to be greatly deviated from half in the communication data signal.

### (Supplementary Note A11)

The processing device according to Supplementary Note 9 or 10, wherein the mark ratio equalizing processing includes processing of performing scrambling on an original signal of the communication data signal and of setting a signal after the scrambling to the communication data signal.

### (Supplementary Note A12)

The processing device according to any one of Supplementary Notes A1 to A11, wherein the identification information includes start information that is provided before the temperature control signal and notifies a start of the temperature control signal.

### (Supplementary Note A13)

The control device according to Supplementary Note A12, wherein the identification information includes end information that notifies an end of the temperature control signal.

### (Supplementary Note A14)

The processing device according to any one of Supplementary Notes A1 to A13, further including a function of performing arithmetic processing.

### (Supplementary Note A15)

The processing device according to any one of Supplementary notes A1 to A14, wherein the another device includes a function of performing arithmetic processing.

### (Supplementary Note A16)

The processing device according to any one of Supplementary Notes A1 to A15 (limited to a supplementary note citing Supplementary Note A2), wherein the drive unit includes a comparator in which a voltage of the temperature control signal and a reference voltage are set as an input signal.

### (Supplementary Note A17)

The processing device according to any one of the Supplementary Notes A1 to A15 (limited to a supplementary note citing Supplementary Note A2), wherein the drive unit includes a comparator in which a voltage of a signal including the temperature control signal and a reference voltage are set as an input signal.

### (Supplementary Note A18)

The processing device according to any one of the Supplementary Notes A1 to A15 (limited to a supplementary note citing Supplementary Note A2), wherein the drive unit includes a comparator in which a voltage of a signal including the temperature control signal and a signal transmitted from the another device are set as an input signal.

### (Supplementary Note A19)

The processing device according to Supplementary Notes A1 to 18, wherein the another device performs sending of a second temperature control signal to the drive unit.

### (Supplementary Note A20)

The processing device according to Supplementary Note A19, wherein the sending is performed when the processing device sends communication data to the another device.

### (Supplementary Note A21)

The processing device according to Supplementary Note A19 or A20, wherein the another device is caused to perform sending of a second temperature control signal to the drive unit.

### (Supplementary Note A22)

The processing device according to any one of Supplementary Notes A19 to A21, wherein at least part of a content of the second temperature control signal is specified for the another device.

### (Supplementary Note B1)

A processing system including:
the processing device according to any one of Supplementary Notes A1 to A22; and
the temperature control means.

### (Supplementary Note B2)

The processing system according to the Supplementary Note B1, further including the another device.

While the invention has been particularly shown and described with reference to example embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent applications No. 2015-165918 filed on Aug. 25, 2015, the disclosure of which is incorporated herein in its entirety by reference.

### REFERENCE SIGNS LIST

1, 001, 101, 201, 401, 501, 601, 901 Processing device
002, 003, 102, 202, 203, 402, 403, 902, 903 Arithmetic device
004, 104, 204, 404, 904 Drive device
504, 604 Comparator
005, 105, 205 Temperature adjusting device
206, 506 Voltage application device
011, 012, 013, 014, 015, 111, 112, 113, 211, 212, 213, 411, 412, 413, 511, 512, 513, 514, 515, 611, 612, 613, 614, 615, 911, 912, 913, 914, 915 Terminal
021, 022, 023, 122a, 122b, 122c, 123z, 123a, 123z, 222a, 222b, 222c, 222z, 223a, 223z, 422a, 422b, 422c, 422z, 423a, 423b, 423c, 423z, 521a, 521c, 522a, 522c, 523, 621a, 621c, 622a, 622c, 623, 922a, 922b, 922c, 923z, 923a, 923z Wire
109, 209, 409, 909 Temperature control device
531, 532, 631, 632, 751, 752 End portion
541, 641, 741 Ground
091, 191, 291, 491, 591, 691, 991 Processing system
551, 651 Base substrate
661 Temperature sensor
106, 971, 972 Signal smoothing device
505, 605, 701 Peltier element
711 Lower conductor
712 Upper conductor
721 P-type semiconductor
731 N-type semiconductor
801, 802, 803, 804, 821, 822, 823, 824 Communication data signal
811, 812, 813, 814 Temperature control signal
161, 861, 863 Start signal
162, 862, 864 End signal
12, 195, 295, 495 Temperature control signal generation unit
13, 196, 296, 496 Data signal generation unit
14, 197, 297, 497 Generation unit
15 Sending unit

1. A processor including:
a temperature control signal generation unit configured to generate a temperature control signal that is to be transmitted to a temperature controller and that has identification information attached thereto for allowing another device communicating with the processor other than the temperature controller to identify the temperature control signal, the temperature controller performing a temperature adjusting output on at least part of the processor and performing, in a process of converting an input signal being input to the temperature adjusting output, high-frequency cutoff processing of allowing a low frequency to pass on the input signal or at least one signal among signals processed from the input signal;
a data signal generation unit configured to generate a communication data signal to be transmitted to the another device;
a transmission signal generation unit configured to generate a transmission signal obtained by superimposing the temperature control signal and the data signal; and
a sending unit configured to send the transmission signal to the temperature controller and the another device.

2. The processor according to claim 1, wherein the temperature controller includes a temperature adjuster for performing the temperature adjusting output and a driver or driving the temperature adjuster, and the driver applies a drive voltage to the temperature adjuster.

3. The processor according to claim 2, wherein the temperature adjuster is a thermoelectric transducer, and the temperature adjusting output is a temperature that affects the at least part.

4. The processor according to claim 1, wherein the high-frequency cutoff processing includes signal smoothing processing of performing signal smoothing by the temperature controller on a communication data signal input to the temperature controller.

5. The processor according to claim 2, wherein the high-frequency cutoff processing includes smoothing processing of the temperature adjusting output performed by the temperature controller when the drive voltage is converted to the temperature adjusting output in the temperature adjuster.

6. The processor according to claim 1, wherein the high-frequency cutoff processing includes mark ratio equalizing processing of setting a mark ratio of the communication data signal of the processor to substantially half.

7. The processor according to claim 1, wherein the another device performs sending of a second temperature control signal to the drive unit.

8. The processor according to claim 7, wherein the sending is performed when the processor sends communication data to the another device.

9. The processor according to claim 7, wherein at least part of a content of the second temperature control signal is specified for the another device.

10. A processing system including:
the processor according to claim 1; and
the temperature controller.
